(19) United States
(12) Patent Application Publication
(10) Pub. No.: US 2025/0063804 A1
(43) Pub. Date: Feb. 20, 2025

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: Suyoung BAE, Suwon-si (KR); Ohseong Kwon, Suwon-si (KR); Jaeyeol Song, Suwon-si (KR); Jeonghyuk Yim, Suwon-si (KR)

(73) Assignee: SAMSUNG ELECTRONICS CO., LTD., Suwon-si (KR)

(21) Appl. No.: 18/668,920

(22) Filed: May 20, 2024

(30) Foreign Application Priority Data
Aug. 16, 2023 (KR) 10-2023-0107224

(51) Int. Cl. H01L 21/8238; H01L 21/308; H01L 27/092

(52) U.S. Cl. CPC H01L 21/823807; H01L 21/3086; H01L 27/092

(57) ABSTRACT

Provided is a semiconductor device and method of manufacturing same, the method including: preparing a substrate including first and second regions; forming a first and second channel patterns in the first and second regions, wherein the first and second channel patterns each include a plurality of semiconductor patterns vertically stacked on the substrate, an inner region, and an outer region; forming a high-k dielectric layer covering the first channel pattern and the second channel pattern; forming a first protective mask on the high-k dielectric layer in the first region and the second region; removing the first protective mask from the first outer region and the second outer region; and forming an additional mask layer surrounding the first channel pattern and the second channel pattern, wherein the additional mask layer does not have etch selectivity with the first protective mask.

### CROSS-REFERENCE TO RELATED APPLICATION

This application is based on and claims priority under 35 U.S.C. § 119 to Korean Patent Application No. 10-2023-0107224, filed on Aug. 16, 2023, in the Korean Intellectual Property Office, the disclosure of which is incorporated by reference herein in its entirety.

### BACKGROUND

### 1. Field

The disclosure relates to a semiconductor device and a method of manufacturing the same, and more particularly, to a semiconductor device including a field effect transistor and a method of manufacturing the semiconductor device.

### 2. Description of Related Art

Semiconductor devices may include an integrated circuit including metal oxide semiconductor field effect transistors (MOSFETs). As sizes and design rules of semiconductor devices are gradually reduced, the scale down of MOSFETs is accelerating. Due to the scale down of MOSFETs, operating characteristics of semiconductor devices may deteriorate. Accordingly, various methods of forming semiconductor devices having excellent performance while overcoming the limitations due to high integration of semiconductor devices have been researched.

### SUMMARY

The disclosure provides a semiconductor device with improved electrical characteristics and reliability.

The disclosure provides a method of manufacturing a semiconductor device with improved electrical characteristics and reliability.

According to an aspect of the disclosure, a method of manufacturing a semiconductor device includes: preparing a substrate including a first region and a second region next to the first region; forming a first channel pattern in the first region and forming a second channel pattern in the second region, wherein the first channel pattern includes a first plurality of semiconductor patterns vertically stacked on the substrate, a first inner region, and a first outer region, and wherein the second channel pattern includes a second plurality of semiconductor patterns vertically stacked on the substrate, a second inner region, and a second outer region; forming a high-k dielectric layer covering the first channel pattern and the second channel pattern; forming a first protective mask on the high-k dielectric layer in the first region and the second region; removing the first protective mask from the first outer region and the second outer region; and forming an additional mask layer surrounding the first channel pattern and the second channel pattern, wherein the additional mask layer does not have etch selectivity with the first protective mask, wherein the first inner region includes spaces between adjacent semiconductor patterns of the first plurality of semiconductor patterns, and the first outer region includes a space around the first plurality of semiconductor patterns excluding the first inner region, and wherein the second inner region includes spaces between adjacent semiconductor patterns of the second plurality of semiconductor patterns, and the second outer region includes a space around the second plurality of semiconductor patterns excluding the second inner region.

According to an aspect of the disclosure, a method of manufacturing a semiconductor device includes: preparing a substrate including a first region and a second region next to the first region; forming a first channel pattern in the first region and forming a second channel pattern in the second region, wherein the first channel pattern includes a first plurality of semiconductor patterns vertically stacked on the substrate, a first inner region, and a first outer region, and wherein the second channel pattern includes a second plurality of semiconductor patterns vertically stacked on the substrate, a second inner region, and a second outer region; forming a first protective mask surrounding the first channel pattern and the second channel pattern; removing the first protective mask from the first outer region and the second outer region; forming an additional mask layer surrounding the first channel pattern and the second channel pattern, wherein the additional mask layer does not have etch selectivity with the first protective mask; forming, on the additional mask layer, a second protective mask having etch selectivity with the first protective mask and the additional mask layer; forming a first photo mask layer covering the second protective mask in the first region; and exposing a sidewall of the second protective mask and a sidewall of the additional mask layer in a boundary between the first region and the second region by removing the second protective mask, the additional mask layer, and the first protective mask from the second region by using the first photo mask layer as an etch mask, wherein the first inner region includes spaces between adjacent semiconductor patterns of the first plurality of semiconductor patterns, and the first outer region includes a space around the first plurality of semiconductor patterns excluding the first inner region, and wherein the second inner region includes spaces between adjacent semiconductor patterns of the second plurality of semiconductor patterns, and the second outer region includes a space around the second plurality of semiconductor patterns excluding the second inner region.

According to an aspect of the disclosure, a method of manufacturing a semiconductor device includes: preparing a substrate including a first region and a second region next to the first region; forming a first channel pattern in the first region and forming a second channel pattern in the second region, wherein the first channel pattern includes a first plurality of semiconductor patterns vertically stacked on the substrate and a first inner region, and wherein the second channel pattern includes a second plurality of semiconductor patterns vertically stacked on the substrate and a second inner region; forming a high-k dielectric layer covering the first channel pattern and the second channel pattern; forming a first protective mask filling the first inner region and the second inner region and surrounding the first channel pattern and the second channel pattern in an outer region, wherein the outer region includes a remaining space on the first plurality of semiconductor patterns and the second plurality of semiconductor patterns excluding the first inner region and the second inner region; exposing at least part of a surface of the high-k dielectric layer by removing the first protective mask from the outer region; forming an additional mask layer covering the exposed surface of the high-k dielectric layer and sidewalls of the first protective mask, wherein the additional mask layer has no etch selectivity with the first protective mask; forming the first protective mask and a second protective mask having etch selectivity with the additional mask layer on the additional mask layer; forming a photo mask layer covering the second protective mask in the first region; and removing the second protective mask, the additional mask layer, and the first protective mask from the second region by using the photo mask layer as an etch mask.

### BRIEF DESCRIPTION OF DRAWINGS

The above and other aspects, features, and advantages of certain embodiments of the present disclosure will be more apparent from the following description taken in conjunction with the accompanying drawings, in which:

FIGS. 1 through 8 are diagrams for explaining a method of manufacturing a semiconductor device according to one or more embodiments;

FIGS. 9 through 16 are diagrams for explaining a method of manufacturing a semiconductor device according to one or more embodiments;

FIGS. 17 through 19 are conceptual diagrams for explaining logic cells of a semiconductor device according to one or more embodiments;

FIG. 20 is a plan view for explaining a semiconductor device according to one or more embodiments;

FIGS. 21A through 21D are cross-sectional views taken along lines A-A′, B-B′, C-C′, and D-D′ of FIG. 20, respectively;

FIG. 22A is an enlarged view showing region M of FIG. 21D according to an embodiment;

FIG. 22B is an enlarged view showing region N of FIG. 21D according to an embodiment;

FIG. 23A is an enlarged view showing the region M of FIG. 21D according to an embodiment; and

FIG. 23B is an enlarged view showing the region N of FIG. 21D according to an embodiment.

### DETAILED DESCRIPTION

Hereinafter, embodiments of the disclosure will be described in detail with reference to the attached drawings.

In the following description, like reference numerals refer to like elements throughout the specification. Well-known functions or constructions are not described in detail since they would obscure the one or more exemplar embodiments with unnecessary detail. As used herein, a plurality of “unit”, “module”, “member”, and “block” may be implemented as a single component or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expression “at least one of a, b or c” indicates “only a,” “only b,” “only c,” “both a and b,” “both a and c,” “both b and c,” or “all of a, b, and c.”

It will be understood that, although the terms first, second, third, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

An identification code is used for the convenience of the description but is not intended to illustrate the order of one or more operations or steps. Each operation or step may be implemented in an order different from the illustrated order unless the context clearly indicates otherwise.

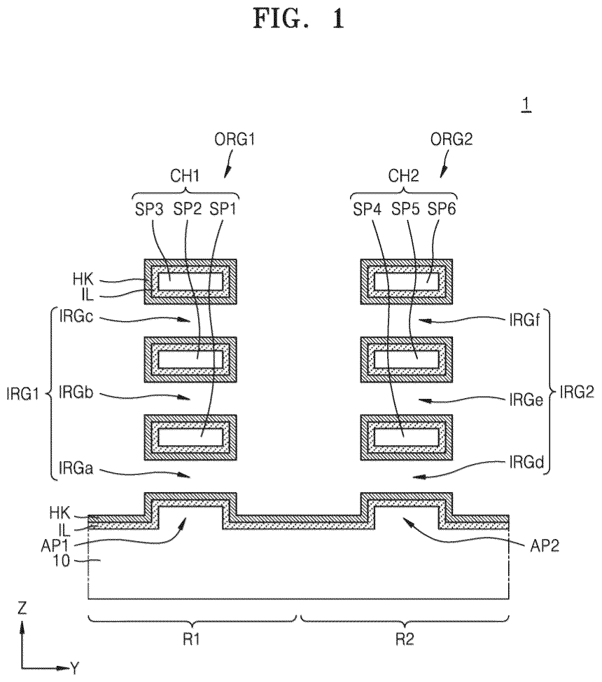

FIGS. 1 to 8 are diagrams for explaining a method of manufacturing a semiconductor device 1 according to one or more embodiments.

Referring to FIG. 1, the semiconductor device 1 including a first region R1 and a second region R2 may be provided according to an embodiment. For example, the first region R1 may include an N-type metal oxide semiconductor field effect transistor (NMOSFET), and the second region R2 may include a P-type metal oxide semiconductor field effect transistor (PMOSFET). MOS is an abbreviation for metal oxide semiconductor, and MOSFET is an abbreviation for MOS field effect transistor. In the drawings, only first and second regions R1 and R2 are shown, but the disclosure is not limited thereto and the semiconductor device 1 may include more regions. The second region R2 may be next to the first region R1 in a first direction Y. The first direction Y is defined as a direction parallel to a top surface of a substrate 10.

The semiconductor device 1 may include the substrate 10, a first channel pattern CH1, and a second channel pattern CH2. The substrate 10 may be a semiconductor substrate including silicon (Si), germanium (Ge), silicon-germanium (SiGe), or a compound semiconductor substrate. As an example, the substrate 100 may be a silicon substrate.

The substrate 10 may include a first active pattern AP1 in the first region R1 and a second active pattern AP2 in the second region R2. The first and second active patterns AP1 and AP2 are part of the substrate 10 and may be vertically protruding parts.

The first channel pattern CH1 may be disposed on the first active pattern AP1. The second channel pattern CH2 may be disposed on the second active pattern AP2. The first channel pattern CH1 may be disposed in the first region R1, and the second channel pattern CH2 may be disposed in the second region R2. The first channel pattern CH1 may include first to third semiconductor patterns SP1 to SP3 spaced apart from each other in a second direction Z. The second channel pattern CH2 may include fourth to sixth semiconductor patterns SP4 to SP6 spaced apart from each other in the second direction Z. The second direction Z is defined as a direction perpendicular to the top surface of the substrate 10. The first to sixth semiconductor patterns SP1 to SP6 may each include silicon, germanium, or silicon-germanium. For example, each of the first to sixth semiconductor patterns SP1 to SP6 may include crystalline silicon.

While some of the drawings do not show certain configurations or structures supporting the first to sixth semiconductor patterns SP1 to SP6, such other configurations or structures may be provided to support the first to sixth semiconductor patterns SP1 to SP6. In the drawings, each of the first channel pattern CH1 and the second channel pattern CH2 is shown as including three semiconductor patterns, but the number of the semiconductor patterns is not limited thereto. In the drawings, the same number of first regions R1 and second regions R2 are shown, but the disclosure is not limited thereto. The number of first regions R1 and the number of second regions R2 may be different from each other.

An interface layer IL may surround the first channel pattern CH1 and the second channel pattern CH2. The interface layer IL may cover the top surface of the substrate 10 and the first and second active patterns AP1 and AP2. The interface layer IL may cover the surface of each of the first to sixth semiconductor patterns SP1 to SP6. A high-k dielectric layer HK may be disposed on the interface layer IL. The high-k dielectric layer HK may cover a surface of the interface layer IL. The interface layer IL may include a silicon oxide layer or a silicon oxynitride layer. The high-k dielectric layer HK may include a high-k dielectric constant material having a higher dielectric constant than the silicon oxide layer. According to the embodiment, the high-k dielectric layer HK may have a uniform thickness.

As an example, the high-k dielectric layer HK may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

An inner region between the substrate 10 and the first semiconductor pattern SP1 in the first region R1 may be referred to as a first portion IRGa. An inner region between the first semiconductor pattern SP1 and the second semiconductor pattern SP2 in the first region R1 may be referred to as a second portion IRGb. An inner region between the second semiconductor pattern SP2 and the third semiconductor pattern SP3 in the first region R1 may be referred to as a third portion IRGc. The first to third portions IRGa to IRGc may be respectively included within widths of the first to third semiconductor patterns SP1 to SP3 in the first direction Y. The first to third portions IRGa to IRGc may be referred to as first inner regions IRG1. Empty spaces within the high-k dielectric layer HK in the first region R1 excluding the first to third portions IRGa to IRGc may be referred to as a first outer region ORG1. The first outer region ORG1 may refer to the remaining space on the first channel pattern CH1 or the high-k dielectric layer HK excluding the first inner regions IRG1.

An inner region between the substrate 10 and the fourth semiconductor pattern SP4 in the second region R2 may be referred to as a fourth portion IRGd. An inner region between the fourth semiconductor pattern SP4 and the fifth semiconductor pattern SP5 in the second region R2 may be referred to as a fifth portion IRGe. An inner region between the fifth semiconductor pattern SP5 and the sixth semiconductor pattern SP6 in the second region R2 may be referred to as a sixth portion IRGf. The fourth to sixth portions IRGd to IRGf may be included within widths of the first to third semiconductor patterns SP4 to SP6 in the first direction Y. The fourth to sixth portions IRGd to IRGf may be referred to as second inner regions IRG2. Empty spaces within the high-k dielectric layer HK in the second region R2 excluding the fourth to sixth portions IRGd to IRGf may be referred to as a second outer region ORG2. The second outer region ORG2 may refer to the remaining space on the second channel pattern CH2 or the high-k dielectric layer HK excluding the second inner regions IRG2.

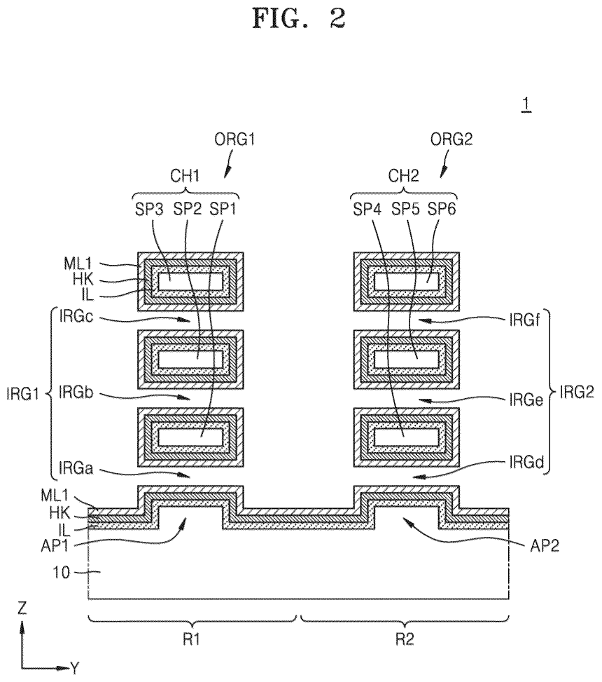

Referring to FIG. 2, a first conductive layer ML1 may be formed on the high-k dielectric layer HK. In an embodiment, the first conductive layer ML1 may cover all surfaces of the high-k dielectric layer HK. The first conductive layer ML1 may not completely fill each of the first to sixth portions IRGa to IRGf. Rather, the first conductive layer ML1 may fill only a part of each of the first to sixth portions IRGa to IRGf. The first conductive layer ML1 may be formed using a physical vapor deposition (PVD), a chemical vapor deposition (CVD), or an atomic layer deposition (ALD).

As an example, the first conductive layer ML1 may include a material having a high-k dielectric constant. For example, the first conductive layer ML1 may include aluminum (Al), magnesium (Mg), calcium (Ca), strontium (Sr), vanadium (V), niobium (Nb), scandium (Sc), and yttrium (Y), or lanthanum (La), or may include a combination thereof, silicate thereof, oxynitride thereof, and/or silicon oxynitride thereof. As an example, the first conductive layer ML1 may include an n-type work function metal (NWFM). For example, the first conductive layer ML1 may include titanium aluminum (TiAl), titanium aluminum carbide (TiAlC), TiAlCN, titanium aluminum nitride (TiAlN), tantalum silicon aluminum (TaSiAl), WCl5, SnCl4, NbCl5, or MoCl4 or a combination thereof. As an example, the first conductive layer ML1 may include a p-type work function metal (PWFM). For example, the first conductive layer ML1 may include titanium (Ti), tantalum (Ta), niobium (Nb), molybdenum (Mo), or tungsten (W), a combination thereof, nitride thereof, oxynitride thereof, and/or oxynitride carbide thereof.

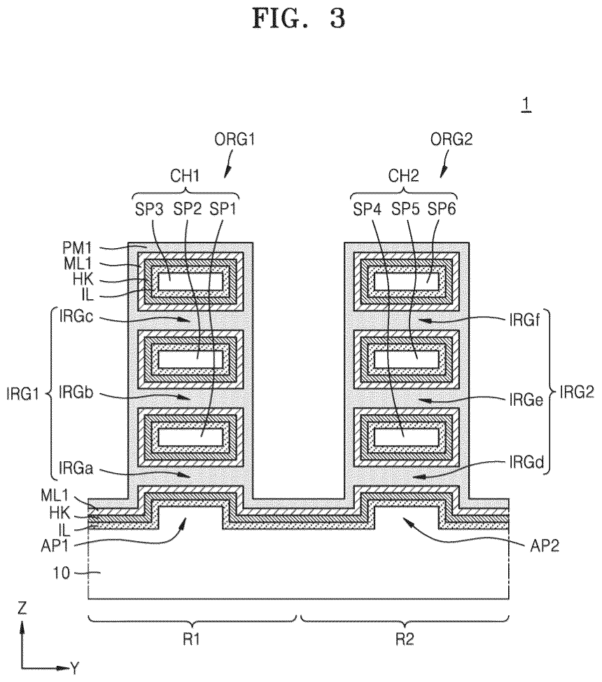

Referring to FIG. 3, a first protective mask PM1 may be formed on the high-k dielectric layer HK to cover the first conductive layer ML1. The first protective mask PM1 may fill the first and second inner regions IRG1 and IRG2. The first protective mask PM1 may fill a part of each of the first and second outer regions ORG1 and ORG2. The first protective mask PM1 may surround the first and second channel patterns CH1 and CH2.

The first protective mask PM1 may include a material that does not react with the high-k dielectric layer HK. For example, the first protective mask PM1 may include aluminum or a mixture of aluminum and another metal, an oxide thereof, a carbide thereof, a silicide thereof, a silicon nitride thereof, and/or a silicon-carbide thereof. Carbide as used herein means metal including carbon atoms. Silicide as used herein means a compound of metal and silicon. Silicon carbide as used herein means metal including silicon and carbon.

The first protective mask PM1 may be formed using PVD, CVD, or ALD. For example, the first protective mask PM1 may be formed through an ALD process using an aluminum precursor.

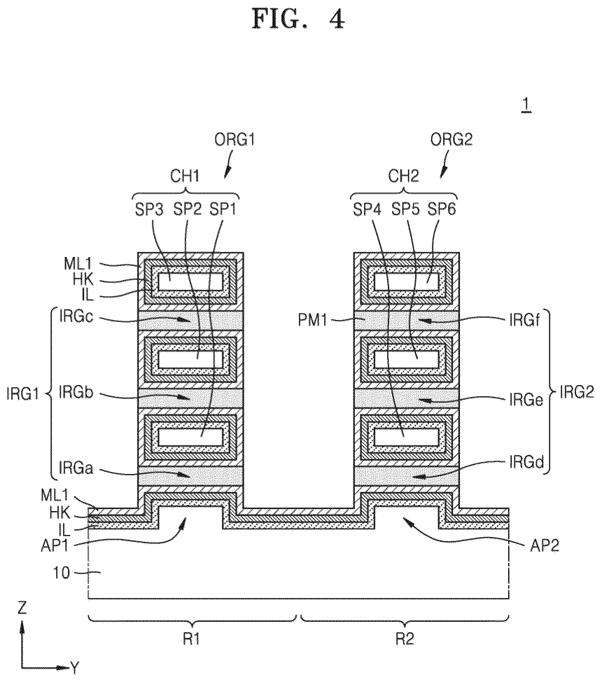

Referring to FIG. 4, the first protective mask PM1 in the first and second outer regions ORG1 and ORG2 may be removed. The first protective mask PM1 may remain in the first and second inner regions IRG1 and IRG2. As a result, a part of surfaces of the first conductive layer ML1 may be exposed. Removing the first protective mask PM1 from the first and second outer regions ORG1 and ORG2 may be performed via wet etching, dry etching, and/or etch-back processes.

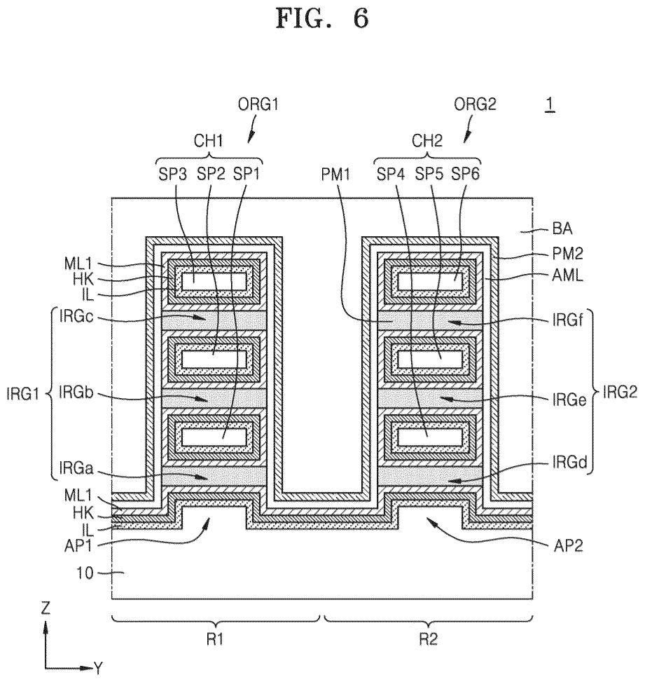

The first protective mask PM1 in the first and second outer regions ORG1 and ORG2 may be removed to facilitate deposition of a photo mask layer BA at a boundary between the first region R1 and the second region R2, which will be described below in FIG. 6. In addition, the first protective mask PM1 in the first and second outer regions ORG1 and ORG2 may be removed to secure an etch margin in a process of separately etching the first region R1 and the second region R2.

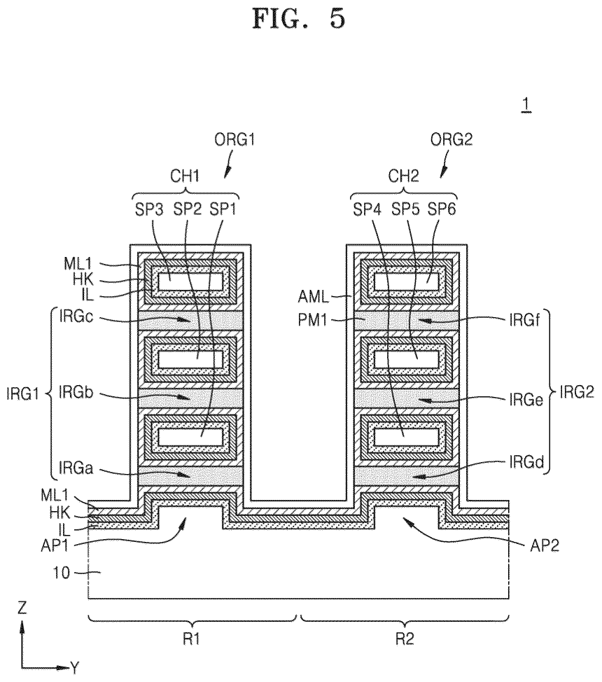

Referring to FIG. 5, an additional mask layer AML may be formed. The additional mask layer AML may cover the exposed surface of the first conductive layer ML1 and sidewalls of the first protective mask PM1. The additional mask layer AML may cover surfaces of other configurations exposed by the first and second outer regions ORG1 and ORG2. The additional mask layer AML may surround the first and second channel patterns CH1 and CH2. A thickness of the additional mask layer AML may be less than a thickness of the first protective mask PM1.

The additional mask layer AML may not have etch selectivity with the first protective mask PM1. The additional mask layer AML may include a material that may be included in the first protective mask PM1. The additional mask layer AML and the first protective mask PM1 may include the same material or different materials. When the additional mask layer AML and the first protective mask PM1 include the same material, no boundary between the additional mask layer AML and the first protective mask PM1 may be observed. The additional mask layer AML may be formed using PVD, CVD, ALD, or a combination thereof.

Referring to FIG. 6, a second protective mask PM2 may be formed to cover the additional mask layer AML. The second protective mask PM2 may cover a surface of the additional mask layer AML exposed in the first and second outer regions ORG1 and ORG2. The second protective mask PM2 may be spaced apart from the first conductive layer ML1 and the high-k dielectric layer HK by the additional mask layer AML formed therebetween. The second protective mask PM2 may include a material having etch selectivity with the first protective mask PM1 and the additional mask layer AML. The second protective mask PM2 may include a material that reacts with the high-k dielectric layer HK. The second protective mask PM2 may include titanium or tantalum alone or a combination thereof, an oxide thereof, a nitride thereof, a carbide thereof, a silicide thereof, a silicon nitride thereof, and/or a silicon carbide thereof.

The photo mask layer BA may be formed covering the second protective mask PM2. The photo mask layer BA may cover the exposed surface of the second protective mask PM2. The photo mask layer BA may fill the first and second outer regions ORG1 and ORG2. The photo mask layer BA may include, for example, bottom anti-reflective coating (BARC).

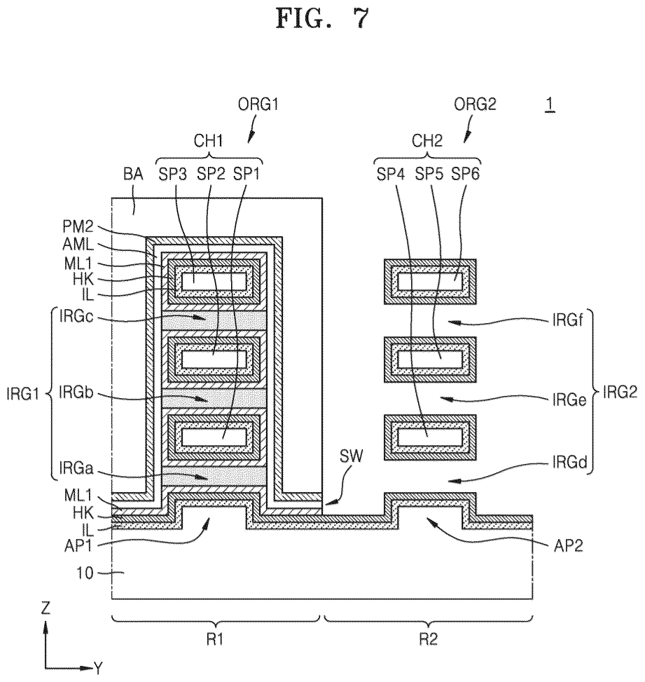

Referring to FIG. 7, the second region R2 may be exposed by removing a part of the photo mask layer BA. In other words, the photo mask layer BA in the second region R2 may be removed.

The second protective mask PM2, the additional mask layer AML, the first protective mask PM1, and the first conductive layer ML1 in the second region R2 may be removed by using the photo mask layer BA as an etch mask. Specifically, the second protective mask PM2 may be removed first, then the additional mask layer AML and the first protective mask PM1 may be removed, and then the first conductive layer ML1 may be removed. The second protective mask PM2, the additional mask layer AML, the first protective mask PM1, and the first conductive layer ML1 may remain in the first region R1. The high-k dielectric layer HK may be exposed in the second region R2.

As the second protective mask PM2, the additional mask layer AML, the first protective mask PM1, and the first conductive layer ML1 in the second region R2 are removed, sidewalls SW of the second protective mask PM2, the additional mask layer AML, and the first conductive layer ML1 may be exposed at a boundary between the first region R1 and the second region R2. In a design where the second protective mask PM2 and the additional mask layer AML each include a material having no etch selectivity with each other, an etch material may be injected into the first region R1 through the sidewalls SW of the second protective mask PM2, the additional mask layer AML, and the first conductive layer ML1. Therefore, during the process of removing the second protective mask PM2, the additional mask layer AML, the first protective mask PM1, and the first conductive layer ML1 in the second region R2. As a result, the first conductive layer ML1 in the first region R1 may be damaged, and thus, the shape desired through patterning may not be achieved, which in turn may degrade the electrical characteristics and reliability of the semiconductor device 1.

According to an embodiment, the second protective mask PM2 may include a material having etch selectivity with the first protective mask PM1 and the additional mask layer AML. Consequently, the second protective mask PM2 may be removed first without removing the additional mask layer AML and the first protective mask PM1, then the additional mask layer AML and first protective mask PM1 may be removed next, and finally the first conductive layer ML1 may be removed. As a result of this staged removal process, the process of removing the second protective mask PM2, the additional mask layer AML, the first protective mask PM1, and the first conductive layer ML1 in the second region R2 does not result in the etch material being injected into the first region R1 through the sidewalls SW of the mask PM2, the additional mask layer AML, and the first conductive layer ML1. Accordingly, damage to the first conductive layer ML1 in the first region R1 by the etch material may be prevented, thereby facilitating the method of manufacturing the semiconductor device 1, and improving the electrical characteristics and reliability of the semiconductor device 1.

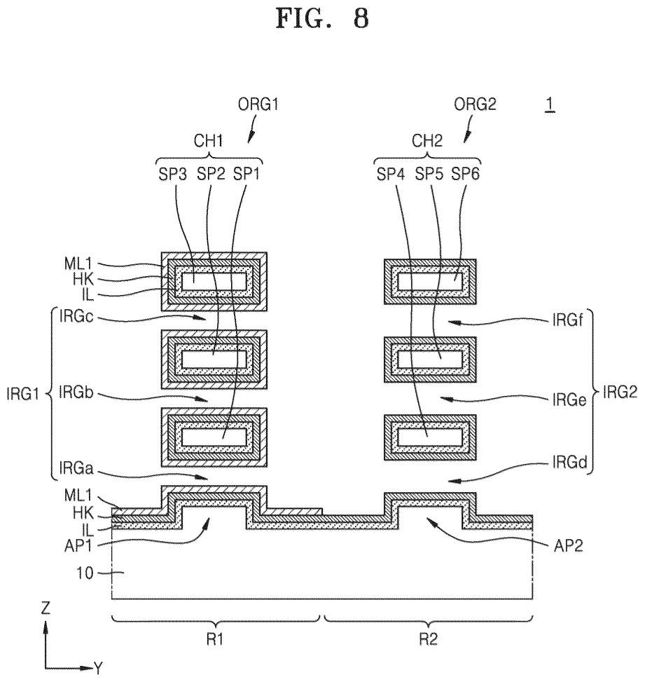

Referring to FIG. 8, the photo mask layer BA, the second protective mask PM2, the additional mask layer AML, and the first protective mask PM1 in the first region R1 may be removed. Accordingly, the first conductive layer ML1 may remain only in the first region R1. The first conductive layer ML1 may surround the first channel pattern CH1 and may not surround the second channel pattern CH2. The high-k dielectric layer HK may be exposed in the fourth to sixth portions IRGd to IRGf in the second region R2 and the second outer region ORG2.

The process of forming the first conductive layer ML1 only in the first region R1 has been described. However, this is only an example, and the first conductive layer ML1 may be formed only in the second region R2. Formation of the first conductive layer ML1 may vary depending on the design of the semiconductor device 1 to be implemented.

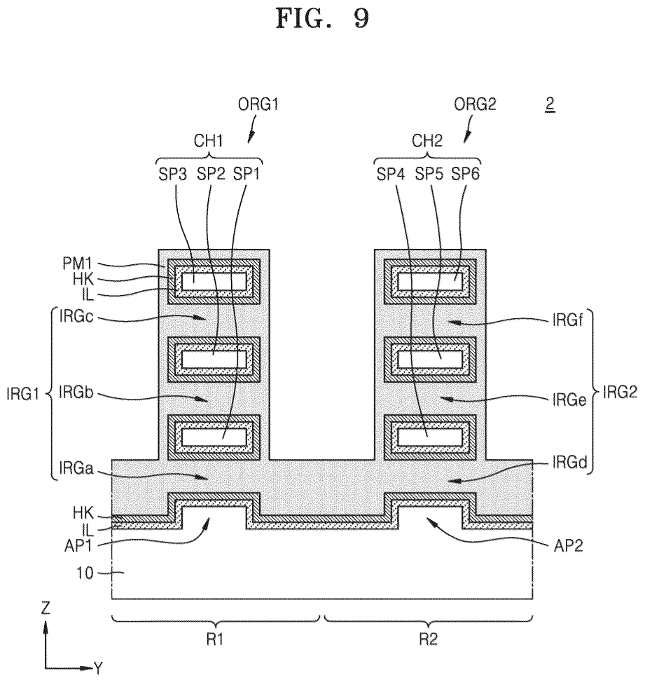

FIGS. 9 to 16 are diagrams for explaining a method of manufacturing a semiconductor device 2 according to one or more embodiments.

Referring to FIG. 9, the semiconductor device 2 may include the substrate 10, the first region R1, the second region R2, the interface layer IL, the high-k dielectric layer HK, the first and second inner regions IRG1 and IRG2, the first and second outer regions ORG1 and ORG2, and the first and second channel patterns CH1 and CH2. The substrate 10, the first region R1, the second region R2, the interface layer IL, the high-k dielectric layer HK, the first and second inner regions IRG1 and IRG2, the first and second outer regions ORG1 and ORG2, and the first and second channel patterns CH1 and CH2 may be the same as those described with reference to FIG. 1.

The first protective mask PM1 may be formed to fill the first and second inner regions IRG1 and IRG2 and the first and second outer regions ORG1 and ORG2. A material included in the first protective mask PM1 may be the same as that described with reference to FIG. 3. A method of forming the first protective mask PM1 may be the same as that described with reference to FIG. 3.

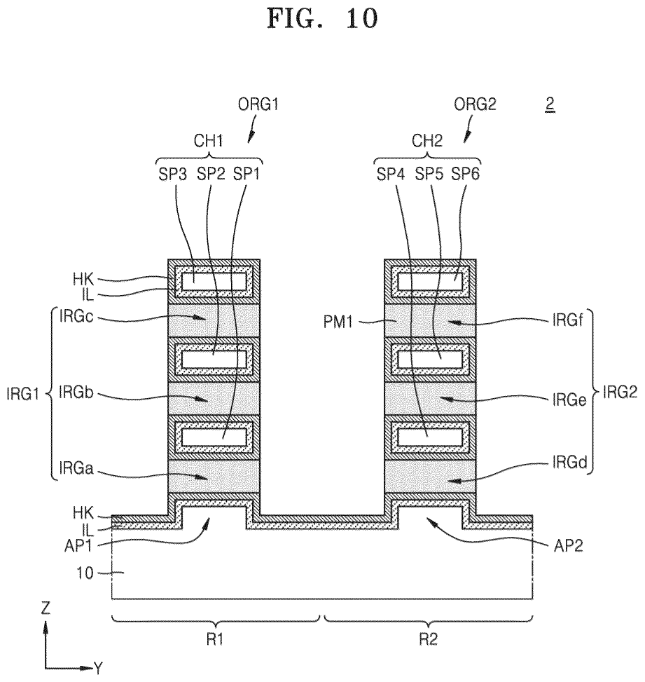

Referring to FIG. 10, the first protective mask PM1 in the first and second outer regions ORG1 and ORG2 may be removed. The first protective mask PM1 may remain in the first and second inner regions IRG1 and IRG2. As a result, some of surfaces of the high-k dielectric layer HK may be exposed. Removing the first protective mask PM1 from the first and second outer regions ORG1 and ORG2 may be performed via wet etching, dry etching, and/or etch-back processes.

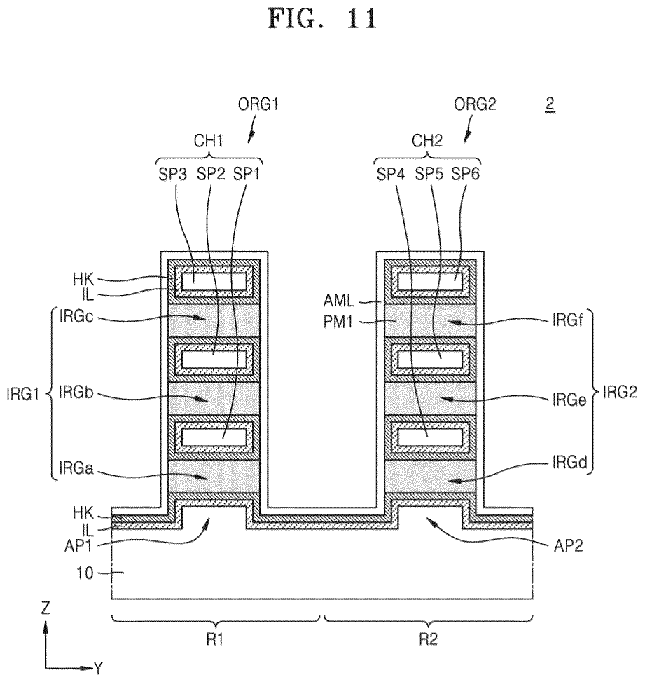

Referring to FIG. 11, the additional mask layer AML may be formed to cover the exposed surfaces of the high-k dielectric layer HK and the sidewalls of the first protective mask PM1. The additional mask layer AML may cover surfaces of other configurations exposed by the first and second outer regions ORG1 and ORG2. A thickness of the additional mask layer AML may be less than a thickness of the first protective mask PM1.

A material included in the additional mask layer AML may be the same as that described with reference to FIG. 5. In an embodiment, there is no boundary between the additional mask layer AML and the first protective mask PM1. The additional mask layer AML may be formed using PVD, CVD, ALD, or a combination thereof.

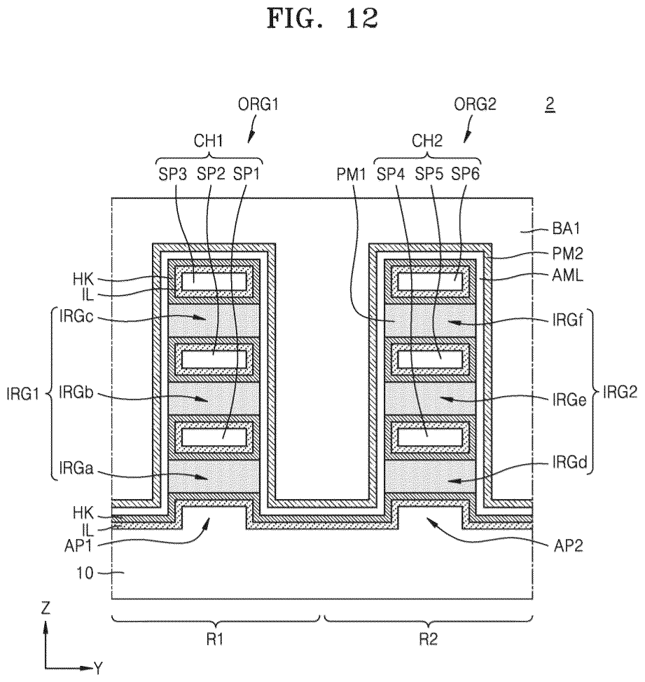

Referring to FIG. 12, the second protective mask PM2 may be formed. The second protective mask PM2 may cover the additional mask layer AML. The second protective mask PM2 may be spaced apart from the high-k dielectric layer HK with the additional mask layer AML disposed therebetween. A material included in the second protective mask PM2 may be the same as that described with reference to FIG. 6.

A first photo mask layer BA1 may be formed to cover the second protective mask PM2. The first photo mask layer BA1 may cover the exposed surface of the second protective mask PM2. The first photo mask layer BA1 may fill the first and second outer regions ORG1 and ORG2. The first photo mask layer BA1 may include, for example, BARC.

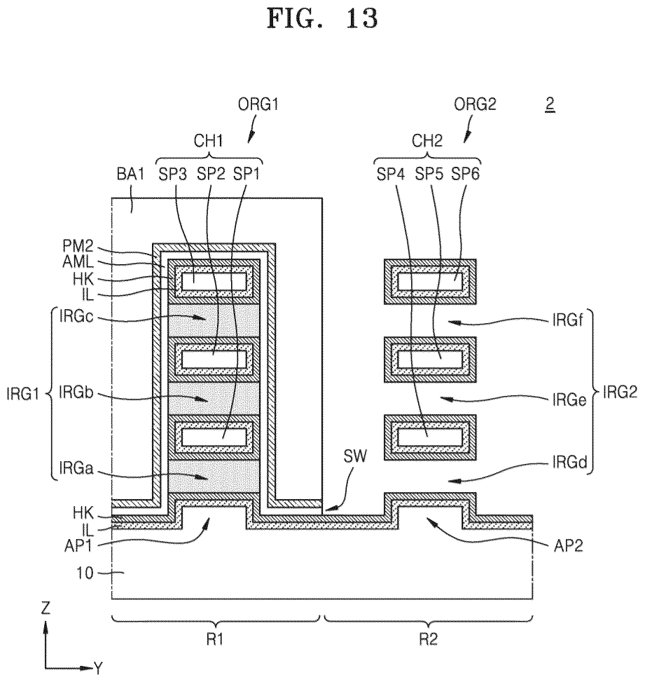

Referring to FIG. 13, the second region R2 may be exposed by removing a part of the first photo mask layer BA1. In other words, the first photo mask layer BA1 in the second region R2 may be removed.

The second protective mask PM2, the additional mask layer AML, and the first protective mask PM1 in the second region R2 may be removed by using the first photo mask layer BA1 as an etch mask. Specifically, the second protective mask PM2 may be removed first, and then the additional mask layer AML and the first protective mask PM1 may be removed. The second protective mask PM2, the additional mask layer AML, the first protective mask PM1, and the first conductive layer ML1 may remain in the first region R1. The high-k dielectric layer HK may be exposed in the second region R2.

As the second protective mask PM2, the additional mask layer AML, and the first protective mask PM1 in the second region R2 are removed, the sidewalls SW of the second protective mask PM2 and the additional mask layer AML may be exposed at a boundary between the first region R1 and the second region R2. In a design where the second protective mask PM2 and the additional mask layer AML are formed from a material having no etch selectivity with one another, an etch material may be injected into the first region R1 through the sidewalls SW of the second protective mask PM2 and the additional mask layer AML during the a process of removing the second protective mask PM2, the additional mask layer AML, and the first protective mask PM1 in the second region R2. In this case, the high-k dielectric layer HK in the first region R1 may be damaged, and thus, the shape desired through patterning may not be achieved, and the electrical characteristics and reliability of the semiconductor device 2 may deteriorate.

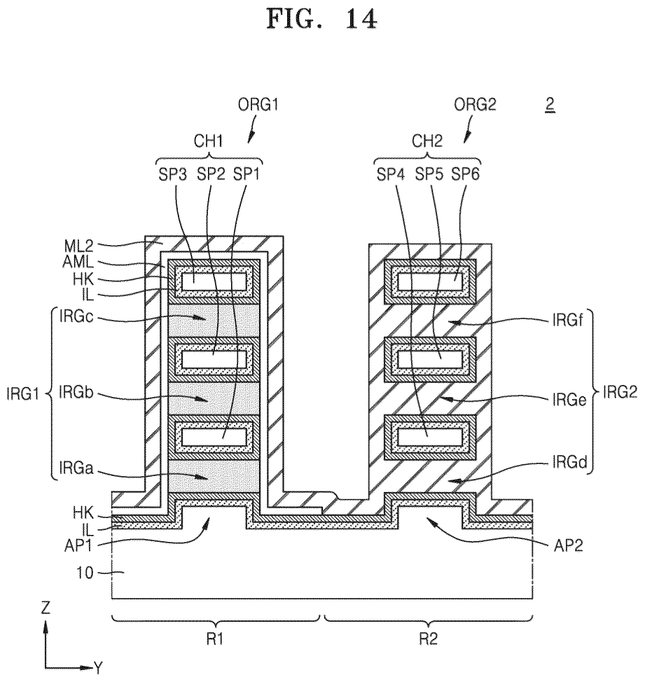

According to an embodiment, the second protective mask PM2 may include a material having etch selectivity with the first protective mask PM1 and the additional mask layer AML. Consequently, the second protective mask PM2 may be removed first without removing the additional mask layer AML and the first protective mask PM1, and then the additional mask layer AML and the first protective mask PM1 may be removed. As a result, the process of removing the second protective mask PM2, the additional mask layer AML, and the first protective mask PM1 in the second region R2, does not result in the etch material being injected into the first region R1 through the sidewalls SW of the mask PM2 and the additional mask layer AML. Accordingly, damage to the high-k dielectric layer HK in the first region R1 by the etch material may be prevented, thereby facilitating the method of manufacturing the semiconductor device 2, and improving the electrical characteristics and reliability of the semiconductor device 2. Referring to FIG. 14, the first photo mask layer BA1 may be removed, and the second conductive layer ML2 may be formed. The second conductive layer ML2 may cover the additional mask layer AML in the first outer region ORG1 of the first region R1. The second conductive layer ML2 may cover the high-k dielectric layer HK in the second region R2. The second conductive layer ML2 may fill the second inner regions IRG2.

The second conductive layer ML2 may include materials that may be included in the first conductive layer ML1 described with reference to FIG. 2. The second conductive layer ML2 may be formed using the method of forming the first conductive layer ML1 with reference to FIG. 2.

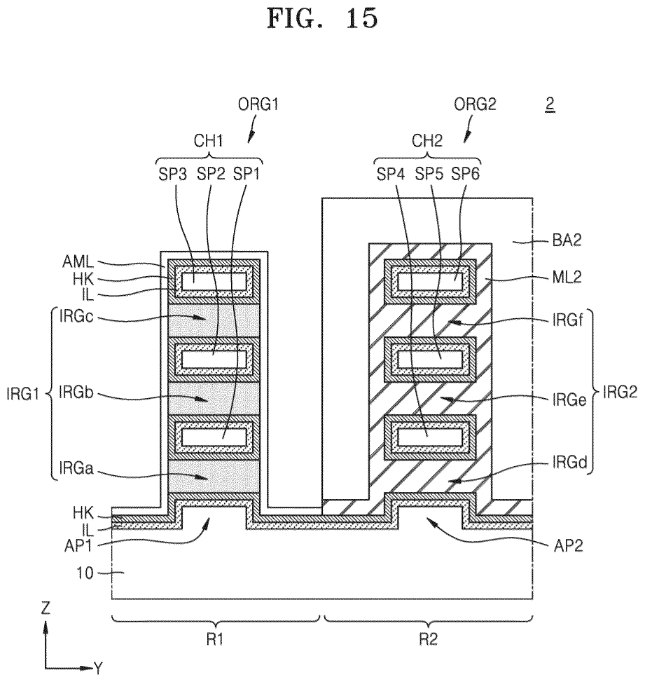

Referring to FIG. 15, a second photo mask layer BA2 may be formed to cover the second conductive layer ML2. The second photo mask layer BA2 may include a material that may be included in the first photo mask layer BA1. The second photo mask layer BA2 in the first region R1 may be removed, and the second conductive layer ML2 may be removed in the first region R1. The second conductive layer ML2 may remain in the second region R2. As the second conductive layer ML2 is removed, the additional mask layer AML may be exposed in the first region R1.

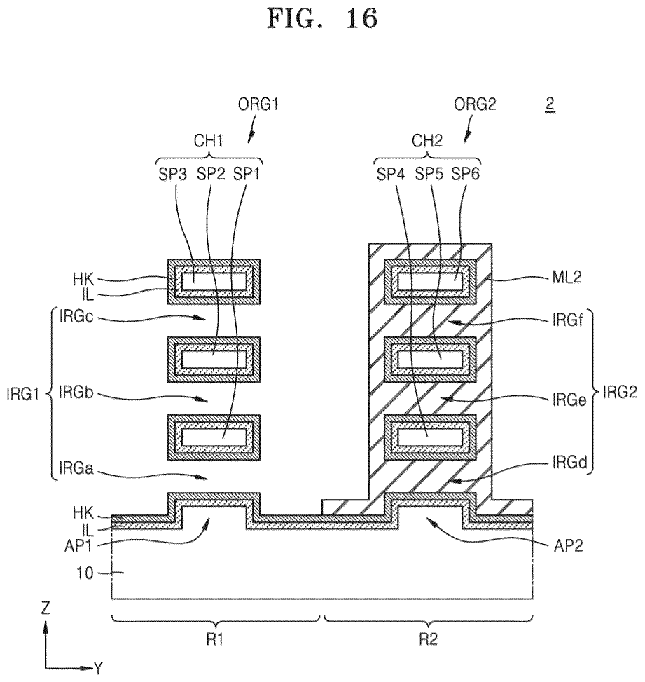

Referring to FIG. 16, the additional mask layer AML may be removed from the first region R1. The second photo mask layer BA2 may be removed from the second region R2. Accordingly, the second conductive layer ML2 may exist only in the second region R2.

With reference to FIGS. 9 to 16, the process of forming the second conductive layer ML2 only in the second region R2 has been described. However, this only corresponds to an embodiment, and the second conductive layer ML2 may be formed only in the first region R1. Placement of the second conductive layer ML2 may vary depending on the design of the semiconductor device 2 to be implemented.

According to an embodiment, after forming the first protective mask PM1 covering the high-k dielectric layer HK, the first protective mask PM1 may be removed from the first and second outer regions ORG1 and ORG2. Thereafter, the additional mask layer AML may be formed to cover the exposed surfaces of the high-k dielectric layer HK and the side surfaces of the first protective mask PM1, and the second protective mask PM2 may be formed to cover the additional mask layer AML. The first protective mask PM1 and the additional mask layer AML may include a material that does not react with the high-k dielectric layer HK, and the second protective mask PM2 may include a material that reacts with the high-k dielectric layer HK. The second protective mask PM2 may be spaced apart from the high-k dielectric layer HK with the additional mask layer AML disposed therebetween. Accordingly, the high-k dielectric layer HK and the second protective mask PM2 are spaced apart and do not react with each other, and thus, loss of the thickness of the high-k dielectric layer HK may be prevented. For the above reasons, the electrical characteristics and reliability of the semiconductor device 2 may be improved.

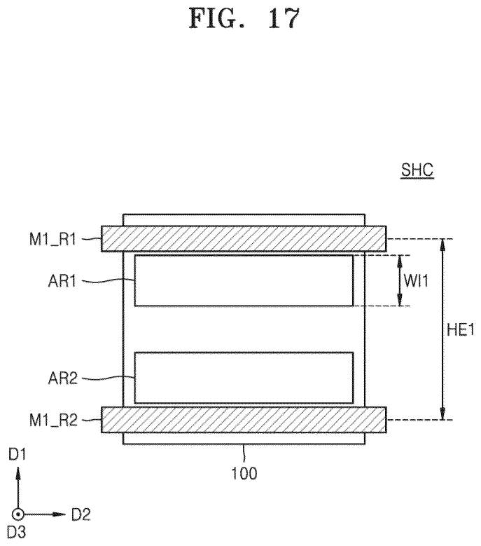

FIGS. 17 to 19 are conceptual diagrams for explaining logic cells of a semiconductor device according to one or more embodiments.

Referring to FIG. 17, a single height cell SHC may be provided. Specifically, a first power wiring M1_R1 and a second power wiring M1_R2 may be provided on a substrate 100. The substrate 100 may correspond to the substrate 10 in FIGS. 1 to 16. The first power wiring M1_R1 may be a path through which a source voltage VSS, for example, a ground voltage, is provided. The second power wiring M1_R2 may be a path through which a drain voltage VDD, for example, a power voltage, is provided.

The single height cell SHC may be defined between the first power wiring M1_R1 and the second power wiring M1_R2. The single height cell SHC may include one first active region AR1 and one second active region AR2. One of the first and second active regions AR1 and AR2 may be a PMOSFET region, and the other of the first and second active regions AR1 and AR2 may be an NMOSFET region. In other words, the single height cell SHC may have a CMOS structure provided between the first power wiring M1_R1 and the second power wiring M1_R2. The first active regions AR1 may correspond to the first region R1 in FIGS. 1 to 16. The second active regions AR2 may correspond to the second region R2 in FIGS. 1 to 16.

Each of the first and second active regions AR1 and AR2 may have a first width WI1 in a first horizontal direction D1. A length of the single height cell SHC in the first horizontal direction D1 may be defined as a first height HE1. The first height HE1 may be substantially the same as a distance (e.g., pitch) between the first power wiring M1_R1 and the second power wiring M1_R2.

As used herein, the first horizontal direction D1 is defined as a direction parallel to a top surface of the substrate 100, the second horizontal direction D2 is defined as a direction parallel to the top surface of the substrate 100 and intersecting with the first horizontal direction D1, and a vertical direction D3 is defined as a direction perpendicular to the top surface of the substrate 100.

The single height cell SHC may constitute one logic cell. In this specification, a logic cell may refer to a logic device (e.g., AND, OR, XOR, XNOR, inverter, etc.) that performs a specific function. That is, the logic cell may include transistors configuring the logic device and wirings connecting the transistors to each other.

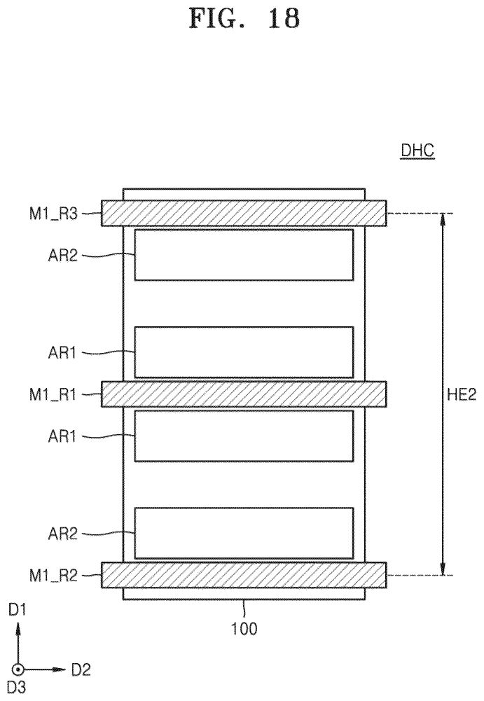

Referring to FIG. 18, a double height cell DHC may be provided. Specifically, the first power wiring M1_R1, the second power wiring M1_R2, and a third power wiring M1_R3 may be provided on the substrate 100. The first power wiring M1_R1 may be disposed between the second power wiring M1_R2 and the third power wiring M1_R3. The third power wiring M1_R3 may be a path through which the source voltage VSS is provided.

The double height cell DHC may be defined between the second power wiring M1_R2 and the third power wiring M1_R3. The double height cell DHC may include two first active regions AR1 and two second active regions AR2.

One of the two second active regions AR2 may be adjacent to the second power wiring M1_R2. The other of the two second active regions AR2 may be adjacent to the third power wiring M1_R3. The two first active regions AR1 may be adjacent to the first power wiring M1_R1. In a plan view, the first power wiring M1_R1 may be disposed between the two first active regions AR1.

A length of the double height cell DHC in the first horizontal direction D1 may be defined as a second height HE2. The second height HE2 may be approximately twice the first height HE1 of FIG. 17. The two first active regions AR1 of the double height cell DHC may be tied together to operate as one active region.

In an embodiment, the double height cell DHC shown in FIG. 18 may be defined as a multi height cell. In an embodiment, a multi height cell may include a triple height cell having a cell height approximately three times that of the single height cell SHC.

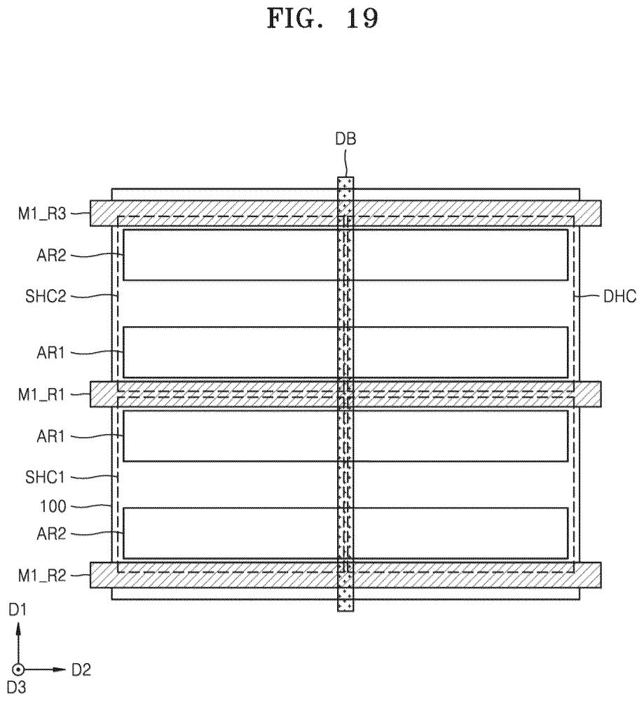

Referring to FIG. 19, a first single height cell SHC1, a second single height cell SHC2, and the double height cell DHC may be two-dimensionally disposed on the substrate 100. The first single height cell SHC1 may be disposed between the first and second power wirings M1_R1 and M1_R2. The second single height cell SHC2 may be disposed between the first and third power wirings M1_R1 and M1_R3. The second single height cell SHC2 may be adjacent to the first single height cell SHC1 in the first horizontal direction D1.

The double height cell DHC may be disposed between the second and third power wirings M1_R2 and M1_R3. The double height cell DHC may be adjacent to the first and second single height cells SHC1 and SHC2 in the second horizontal direction D2.

A separation structure DB may be provided between the first single height cell SHC1 and the double height cell DHC, and between the second single height cell SHC2 and the double height cell DHC. The separation structure DB may electrically separate an active region of the double height cell DHC from an active region of each of the first and second single height cells SHC1 and SHC2.

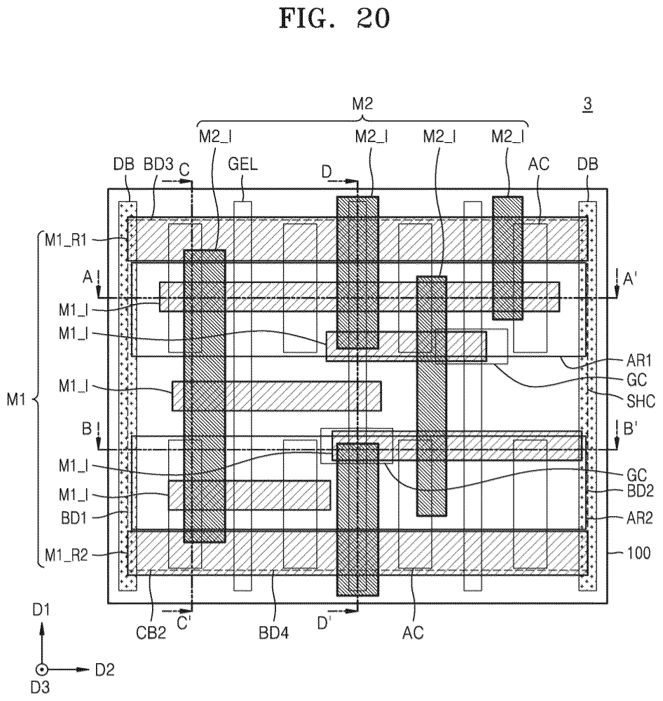

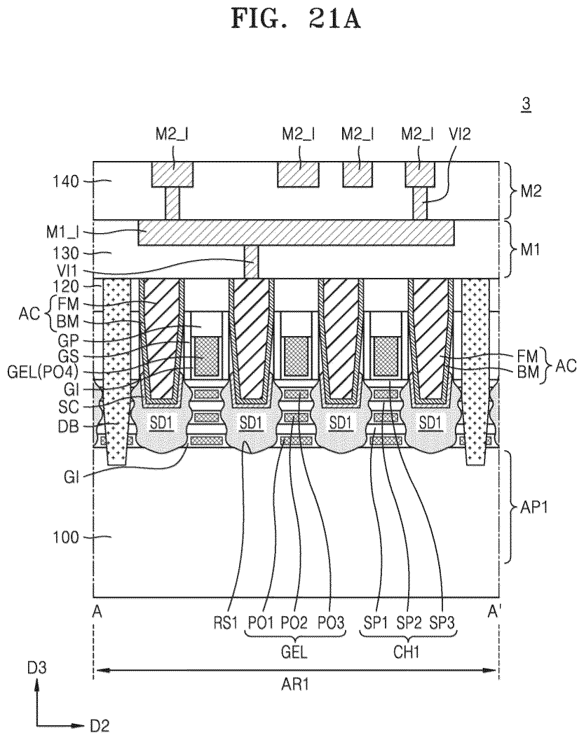

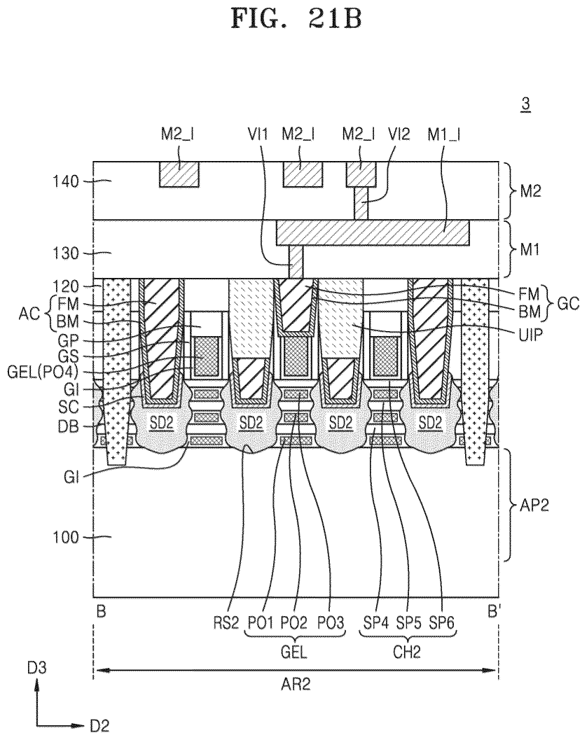

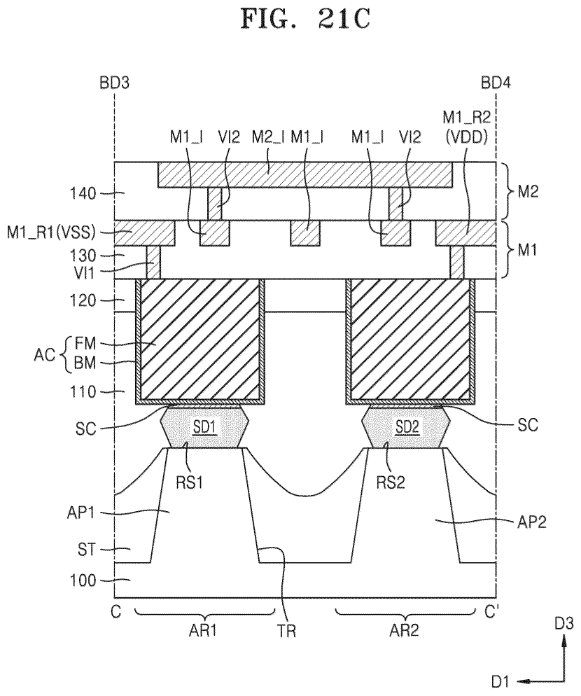

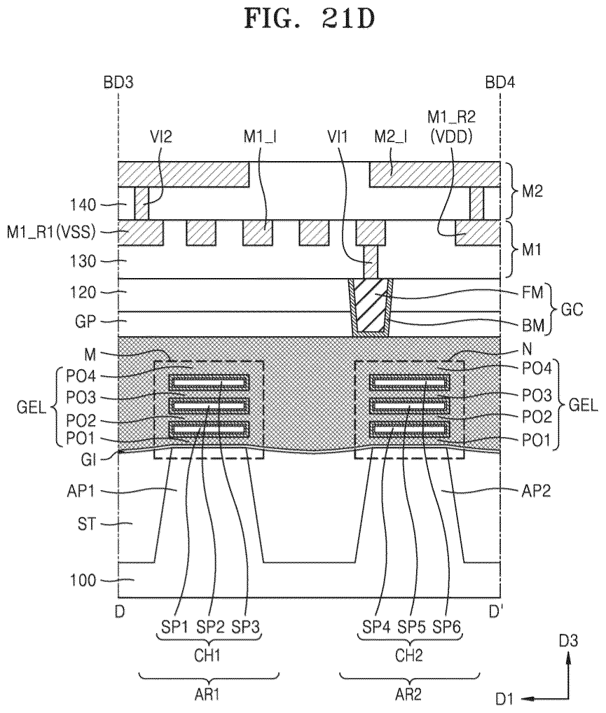

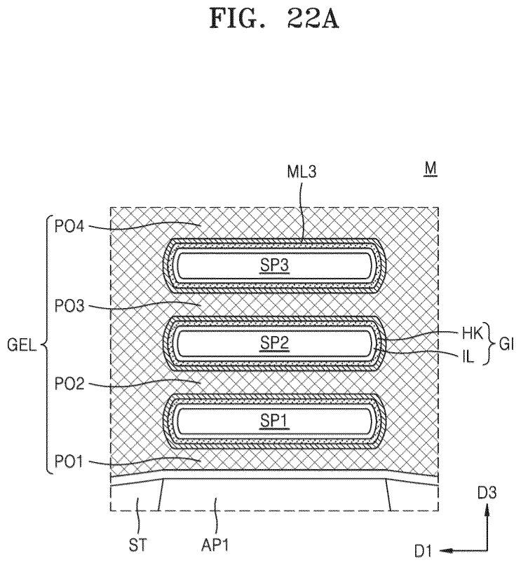

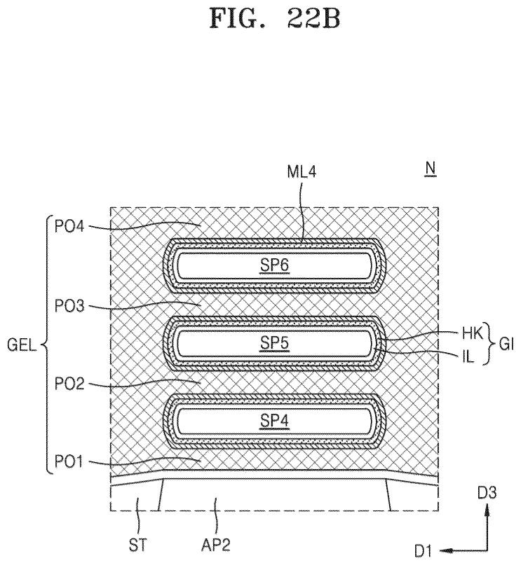

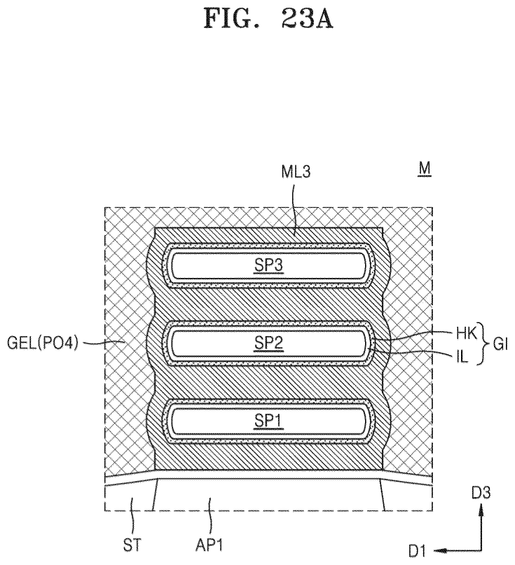

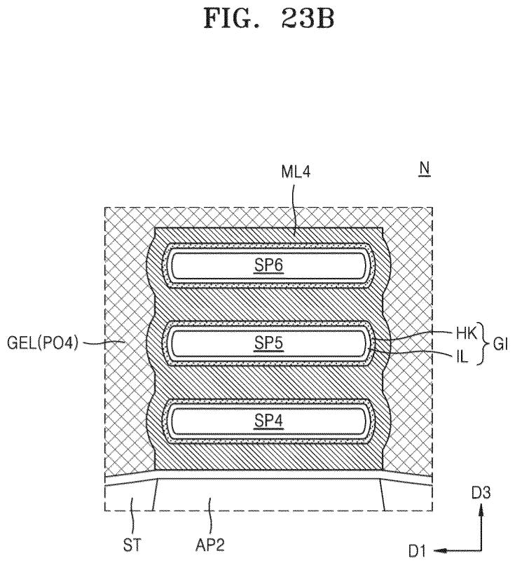

FIG. 20 is a plan view for explaining a semiconductor device 3 according to one or more embodiments. FIGS. 21A to 21D are cross-sectional views taken along lines A-A′, B-B′, C-C′, and D-D′ of FIG. 20, respectively. FIG. 22A is an enlarged view showing region M of FIG. 21D according to an embodiment. FIG. 22B is an enlarged view showing region N of FIG. 21D according to an embodiment. FIG. 23A is an enlarged view showing the region M of FIG. 21D according to an embodiment. FIG. 23B is an enlarged view showing the region N of FIG. 21D according to an embodiment. The semiconductor device 3 shown in FIGS. 20 and 21A to 21D is an example more specifically showing the single height cell SHC of FIG. 17.

Referring to FIGS. 20 and 21A to 21D, the single height cell SHC may be provided on the substrate 100. Logic transistors constituting a logic circuit may be disposed on the single height cell SHC. The substrate 100 may be a semiconductor substrate including silicon, germanium, silicon-germanium, etc., or a compound semiconductor substrate. As an example, the substrate 100 may be a silicon substrate.

The substrate 100 may include the first active region AR1 and the second active region AR2. Each of the first and second active regions AR1 and AR2 may extend in the second horizontal direction D2. In an embodiment, the first active region AR1 may be an NMOSFET region, and the second active region AR2 may be a PMOSFET region.

The first active pattern AP1 and the second active pattern AP2 may be defined by a trench TR formed in an upper portion of the substrate 100. The first active pattern AP1 may be provided on the first active region AR1, and the second active pattern AP2 may be provided on the second active region AR2. The first and second active patterns AP1 and AP2 may extend in the second horizontal direction D2. The first and second active patterns AP1 and AP2 are part of the substrate 100 and may be vertically protruding parts.

A device isolation layer ST may be provided on the substrate 100. The device isolation layer ST may fill the trench TR. The device isolation layer ST may include a silicon oxide layer. The device isolation layer ST may not cover the first and second channel patterns CH1 and CH2, which will be described below.

The first channel pattern CH1 may be provided on the first active pattern AP1. The second channel pattern CH2 may be provided on the second active pattern AP2. The first channel pattern CH1 may include the first semiconductor pattern SP1, the second semiconductor pattern SP2, and the third semiconductor pattern SP3 which are sequentially stacked. The second channel pattern CH2 may include the fourth semiconductor pattern SP4, the fifth semiconductor pattern SP5, and the sixth semiconductor pattern SP6 which are sequentially stacked. The first to third semiconductor patterns SP1 to SP3 may be spaced apart from each other in the vertical direction D3. The fourth to sixth semiconductor patterns SP4 to SP6 may be spaced apart from each other in the vertical direction D3.

Each of the first to sixth semiconductor patterns SP1 to SP6 may include silicon (Si), germanium (Ge), or silicon-germanium (SiGe). For example, each of the first to sixth semiconductor patterns SP1 to SP6 may include crystalline silicon.

A plurality of first source/drain patterns SD1 may be provided on the first active pattern AP1. A plurality of first recesses RS1 may be formed in the first active pattern AP1. The first source/drain patterns SD1 may be respectively provided in the first recesses RS1. The first source/drain patterns SD1 may be impurity regions of a first conductivity type (e.g., n-type). The first channel pattern CH1 may be disposed between a pair of first source/drain patterns SD1. In other words, the stacked first to third semiconductor patterns SP1 to SP3 may connect the pair of first source/drain patterns SD1 to each other.

A plurality of second source/drain patterns SD2 may be provided on the second active pattern AP2. A plurality of second recesses RS2 may be formed in the second active pattern AP2. The second source/drain patterns SD2 may be respectively provided in the second recesses RS2. The second source/drain patterns SD2 may be impurity regions of a second conductivity type (e.g., p-type). The second channel pattern CH2 may be disposed between a pair of second source/drain patterns SD2. In other words, the stacked fourth to sixth semiconductor patterns SP4 to SP6 may connect the pair of second source/drain patterns SD2 to each other.

The first and second source/drain patterns SD1 and SD2 may be epitaxial patterns formed through a selective epitaxial growth (SEG) process. For example, a top surface of each of the first source/drain patterns SD1 may be higher than a top surface of the third semiconductor pattern SP3. A top surface of each of the second source/drain patterns SD2 may be higher than a top surface of the sixth semiconductor pattern SP6. As another example, the top surface of at least one of the first source/drain patterns SD1 may be located at substantially the same level as the top surface of the third semiconductor pattern SP3. As another example, the top surface of at least one of the second source/drain patterns SD2 may be located at substantially the same level as the top surface of the sixth semiconductor pattern SP6.

In an embodiment, the first source/drain patterns SD1 may each include the same semiconductor element (e.g., Si) as that of the substrate 100. The second source/drain patterns SD2 may each include a semiconductor element (e.g., SiGe) having a lattice constant greater than a lattice constant of a semiconductor element of the substrate 100. Accordingly, the pair of second source/drain patterns SD2 may provide compressive stress to the second channel pattern CH2 therebetween.

A sidewall of each of the first and second source/drain patterns SD1 and SD2 may have an uneven shape. In other words, the sidewall of each of the first and second source/drain patterns SD1 and SD2 may have a wavy profile. The sidewall of each of the first and second source/drain patterns SD1 and SD2 may protrude toward first to third gate portions PO1, PO2, and PO3 of the gate electrode GEL, which will be described below.

Gate electrodes GEL may be provided crossing the first and second channel patterns CH1 and CH2 and extending in the first horizontal direction D1. The gate electrodes GEL may be arranged in the second horizontal direction D2 according to a first pitch. The gate electrodes GEL may vertically overlap the first and second channel patterns CH1 and CH2 respectively.

The gate electrode GEL may include a first gate portion PO1 disposed between the first or second active pattern AP1 or AP2 and the first semiconductor pattern SP1, a second gate portion PO2 disposed between the first semiconductor pattern SP1 and the second semiconductor pattern SP2, a third gate portion PO3 disposed between the second semiconductor pattern SP2 and the third semiconductor pattern SP3, and a fourth gate portion PO4 on the third semiconductor pattern SP3.

Referring to FIG. 21D, the gate electrode GEL may be provided on a top surface TS, a bottom surface BS, and both sidewalls SW of each of the first to sixth semiconductor patterns SP1 to SP6. In other words, a transistor according to the embodiment may be a three-dimensional FET (e.g., MBCFET or GAAFET) in which the gate electrode GEL three-dimensionally surrounds a channel. The gate electrode GEL may include metal having a lower resistance than each of a third conductive layer ML3 and fourth conductive layer ML4 of FIGS. 22A to 23B. For example, the gate electrode GEL may include at least one metal selected from the group consisting of tungsten (W), aluminum (Al), titanium (Ti), and tantalum (Ta).

Referring again to FIGS. 20 and 21A to 21D, a pair of gate spacers GS may be disposed on both sidewalls of the fourth gate portion PO4 of the gate electrode GEL. The gate spacers GS may extend in the first horizontal direction D1 along the gate electrode GEL. Top surfaces of the gate spacers GS may be higher than a top surface of the gate electrode GEL. The top surfaces of the gate spacers GS may be coplanar with a top surface of a first interlayer insulating layer 110, which will be described below. In an embodiment, the gate spacers GS may include at least one of SiCN, SiCON, and SiN. In another embodiment, the gate spacers GS may include a multi-layer including at least two of SiCN, SiCON, and SiN.

A gate capping pattern GP may be provided on the gate electrode GEL. The gate capping pattern GP may extend in the first horizontal direction D1 along the gate electrode GEL. The gate capping pattern GP may include a material having etch selectivity with first and second interlayer insulating layers 110 and 120, which will be described below. Specifically, the gate capping pattern GP may include at least one of SiON, SiCN, SiCON, and SiN.

A gate insulating layer GI may be disposed between the gate electrode GEL and the first channel pattern CH1 and between the gate electrode GEL and the second channel pattern CH2. The gate insulating layer GI may cover the top surface TS, the bottom surface BS, and both sidewalls SW of each of the first to sixth semiconductor patterns SP1 to SP6. The gate insulating layer GI may cover the top surface of the device isolation layer ST below the gate electrode GEL.

In an embodiment, referring to FIGS. 22A and 22B, the gate insulating layer GI may include the interface layer IL and the high-k dielectric layer HK. The interface layer IL may include a silicon oxide layer or a silicon oxynitride layer. The high-k dielectric layer HK may include a high-k dielectric constant material having a higher dielectric constant than the silicon oxide layer. According to the embodiment, the high-k dielectric layer HK may have a uniform thickness. As an example, the high-k dielectric layer HK may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In another embodiment, the semiconductor device of the disclosure may include a negative capacitance (NC) FET using a negative capacitor. For example, the gate insulating layer GI may include a ferroelectric material layer having ferroelectric characteristics and a paraelectric material layer having paraelectric characteristics.

In the first active region AR1, the third conductive layer ML3 may be disposed between the gate electrode GEL and the high-k dielectric layer HK. The third conductive layer ML3 may be provided on the gate insulating layer GI and adjacent to the first to third semiconductor patterns SP1 to SP3. The third conductive layer ML3 may include the same material as the material that may be included in each of the first conductive layer ML1 and the second conductive layer ML2 described with reference to FIGS. 1 to 16. The third conductive layer ML3 may function to adjust a threshold voltage of the transistor. The desired threshold voltage of the transistor may be achieved by adjusting the thickness and composition of the third conductive layer ML3. In an embodiment, the third conductive layer ML3 may only partially fill between the first active pattern AP1 and the first semiconductor pattern SP1, between the first semiconductor pattern SP1 and the second semiconductor pattern SP2, and between the second semiconductor pattern SP2 and the third semiconductor pattern SP3, but may not completely fill therebetween. The third conductive layer ML3 may include a plurality of stacked layers. According to an embodiment, the third conductive layer ML3 may be omitted.

In the second active region AR2, the fourth conductive layer ML4 may be disposed between the gate electrode GEL and the high-k dielectric layer HK. The fourth conductive layer ML4 may be provided on the gate insulating layer GI and adjacent to the fourth to sixth semiconductor patterns SP4 to SP6. The fourth conductive layer ML4 may include the same material as the material that may be included in each of the first conductive layer ML1 and the second conductive layer ML2 described with reference to FIGS. 1 to 16. The fourth conductive layer ML4 may perform a function of adjusting the threshold voltage of the transistor. The desired threshold voltage of the transistor may be achieved by adjusting the thickness and composition of the fourth conductive layer MLA. In an embodiment, the fourth conductive layer ML4 may only partially fill between the second active pattern AP2 and the fourth semiconductor pattern SP4, between the fourth semiconductor pattern SP4 and the fifth semiconductor pattern SP5, and between the fifth semiconductor pattern SP5 and the sixth semiconductor pattern SP6, but may not completely fill therebetween. The fourth conductive layer ML4 may include a plurality of stacked layers. According to an embodiment, the fourth conductive layer ML4 may be omitted.

With reference to FIGS. 23A and 23B, the third conductive layer ML3 and the fourth conductive layer ML4 will be described in detail. Hereinafter, redundant descriptions with respect to the third conductive layer ML3 and the fourth conductive layer MLA described above with reference to FIGS. 22A and 22B are omitted, and only the differences are described in detail.

Referring to FIGS. 23A and 23B, in the first active region AR1, the third conductive layer ML3 may completely fill between the first active pattern AP1 and the first semiconductor pattern SP1, between the first semiconductor pattern SP1 and the second semiconductor pattern SP2, and between the second semiconductor pattern SP2 and the third semiconductor pattern SP3. In the second active region AR2, the fourth conductive layer ML4 may completely fill between the second active pattern AP2 and the fourth semiconductor pattern SP4, between the fourth semiconductor pattern SP4 and the fifth semiconductor pattern SP5, and between the fifth semiconductor pattern SP5 and the sixth semiconductor pattern SP6.

Referring again to FIGS. 20 and 21A to 21D, the first interlayer insulating layer 110 may be provided on the substrate 100. The first interlayer insulating layer 110 may cover the gate spacers GS and the first and second source/drain patterns SD1 and SD2. A top surface of the first interlayer insulating layer 110 may be substantially coplanar with a top surface of the gate capping pattern GP and a top surface of the gate spacer GS. The second interlayer insulating layer 120 may be disposed on the first interlayer insulating layer 110 to cover the gate capping pattern GP. A third interlayer insulating layer 130 may be provided on the second interlayer insulating layer 120. A fourth interlayer insulating layer 140 may be provided on the third interlayer insulating layer 130. As an example, the first to fourth interlayer insulating layers 110 to 140 may each include a silicon oxide layer.

The single height cell SHC may have a first boundary BD1 and a second boundary BD2 facing each other in the second horizontal direction D2. The first and second boundaries BD1 and BD2 may extend in the first horizontal direction D1. The single height cell SHC may have a third boundary BD3 and a fourth boundary BD4 facing each other in the first horizontal direction D1. The third and fourth boundaries BD3 and BD4 may extend in the second horizontal direction D2.

A pair of separation structures DB facing each other in the second horizontal direction D2 may be provided on both sides of the single height cell SHC. For example, the pair of separation structures DB may be provided on the first and second boundaries BD1 and BD2 of the single height cell SHC, respectively. The separation structure DB may extend parallel to the gate electrodes GEL in the first horizontal direction D1. A pitch between the separation structure DB and the gate electrode GEL adjacent thereto may be the same as the first pitch.

The separation structure DB may penetrate the first and second interlayer insulating layers 110 and 120 and extend into the first and second active patterns AP1 and AP2. The separation structure DB may penetrate the upper portion of each of the first and second active patterns AP1 and AP2. The isolation structure DB may electrically separate an active region of the single height cell SHC from active regions of other adjacent cells.

Active contacts AC penetrating first and second interlayer insulating layers 110 and 120 and electrically connected to the first and second source/drain patterns SD1 and SD2, respectively, may be provided A pair of active contacts AC may be provided on both sides of the gate electrode GEL, respectively. In a plan view, the active contact AC may have a bar shape extending in the first horizontal direction D1.

The active contact AC may be a self-aligned contact. In other words, the active contact AC may be formed in a self-aligned manner by using the gate capping pattern GP and the gate spacer GS. For example, the active contact AC may cover at least a part of the sidewall of the gate spacer GS. The active contact AC may cover a part of the top surface of the gate capping pattern GP.

A metal-semiconductor compound layer SC, for example, a silicide layer, may be disposed each between the active contact AC and the first source/drain pattern SD1 and between the active contact AC and the second source/drain pattern SD2. The active contact AC may be electrically connected to the source/drain patterns SD1 and SD2 through the metal-semiconductor compound layer SC. For example, the metal-semiconductor compound layer SC may include at least one of titanium-silicide, tantalum-silicide, tungsten-silicide, nickel-silicide, and cobalt-silicide.

Gate contacts GC penetrating the second interlayer insulating layer 120 and the gate capping pattern GP and electrically connected to the gate electrodes GEL, respectively, may be provided. In a plan view, the gate contacts GC may be arranged to overlap the first active region AR1 and the second active region AR2, respectively. As an example, the gate contact GC may be provided on the second active pattern AP2 (see FIG. 21B).

In an embodiment, referring to FIG. 21B, an upper portion of the active contact AC adjacent to the gate contact GC may be filled with an upper insulating pattern UIP. A bottom surface of the upper insulating pattern UIP may be lower than a bottom surface of the gate contact GC. In other words, the top surface of the active contact AC adjacent to the gate contact GC may be lowered than the bottom surface of the gate contact GC by the upper insulating pattern UIP. As a result, a short circuit may be prevented from occurring when the gate contact GC contacts the active contact AC adjacent thereto.

Each of the active contact AC and the gate contact GC may include a conductive pattern FM and a barrier pattern BM surrounding the conductive pattern FM. For example, the conductive pattern FM may include at least one metal selected from aluminum, copper, tungsten, molybdenum, and cobalt. The barrier pattern BM may cover sidewalls and bottom surface of the conductive pattern FM. The barrier pattern BM may include a metal layer/metal nitride layer. The metal layer may include at least one of titanium, tantalum, tungsten, nickel, cobalt, and platinum. The metal nitride layer may include at least one of titanium nitride (TiN), tantalum nitride (TaN), tungsten nitride (WN), nickel nitride (NiN), cobalt nitride (CON), and platinum nitride (PtN).

A first metal layer M1 may be provided in the third interlayer insulating layer 130. For example, the first metal layer M1 may include the first power wiring M1_R1, the second power wiring M1_R2, and first wirings M1_I. The first power wiring M1_R1, the second power wiring M1_R2, and first wirings M1_I of the first metal layer M1 may extend parallel to each other in the second horizontal direction D2.

Specifically, the first and second power wirings M1_R1 and M1_R2 may be provided on the third and fourth boundaries BD3 and BD4 of the single height cell SHC, respectively. The first power wiring M1_R1 may extend in the second horizontal direction D2 along the third boundary BD3. The second power wiring M1_R2 may extend in the second horizontal direction D2 along the fourth boundary BD4.

The first wirings M1_I of the first metal layer M1 may be disposed between the first and second power wirings M1_R1 and M1_R2. The first wirings M1_I of the first metal layer M1 may be arranged along the first horizontal direction D1 at a second pitch. The second pitch may be less than the first pitch. A line width of each of the first wirings M1_I may be less than a line width of each of the first and second power wirings M1_R1 and M1_R2.

The first metal layer M1 may further include first vias VI1. The first vias VI1 may be provided below the first power wiring M1_R1, the second power wiring M1_R2, and first wirings M1_I of the first metal layer M1, respectively. The active contact AC and each of the first power wiring M1_R1, the second power wiring M1_R2, and first wirings M1_I of the first metal layer M1 may be electrically connected to each other through the first via VI1. The gate contact GC and each of the first power wiring M1_R1, the second power wiring M1_R2, and first wirings M1_I of the first metal layer M1 may be electrically connected to each other through the first via VI1.

Each of the first power wiring M1_R1, the second power wiring M1_R2, and first wirings M1_I of the first metal layer M1 and the first via VI1 therebelow may be formed through separate processes. In other words, each of the first power wiring M1_R1, the second power wiring M1_R2, and first wirings M1_I of the first metal layer M1 and the first via VI1 may be formed through a single damascene process.

The second metal layer M2 may be provided in the fourth interlayer insulating layer 140. The second metal layer M2 may include a plurality of second wirings M2_I. Each of the second wirings M2_I of the second metal layer M2 may have a line shape or a bar shape extending in the first horizontal direction D1. In other words, the second wirings M2_I may extend parallel to each other in the first horizontal direction D1.

The second metal layer M2 may further include second vias VI2 respectively provided below the second wirings M2_I. The first power wiring M1_R1, the second power wiring M1_R2, and first wirings M1_I of the first metal layer M1 and the second wirings M2_I of the second metal layer M2 may be electrically connected to each other through the second via VI2. For example, each of the second wirings M2_I of the second metal layer M2 and the second via VI2 therebelow may be formed together through a dual damascene process.

The first power wiring M1_R1, the second power wiring M1_R2, and first wirings M1_I of the first metal layer M1 and the second wirings M2_I of the second metal layer M2 may include the same or different conductive materials. For example, the first power wiring M1_R1, the second power wiring M1_R2, and first wirings M1_I of the first metal layer M1 and the second wirings M2_I of the second metal layer M2 may each include at least one metal material selected from aluminum, copper, tungsten, molybdenum, ruthenium, and cobalt. Metal layers (e.g., M3, M4, M5 . . . ) stacked on the fourth interlayer insulating layer 140 may be additionally disposed. Each of the stacked metal layers may include wirings for routing between cells.

While the disclosure has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
preparing a substrate comprising a first region and a second region next to the first region;
forming a first channel pattern in the first region and forming a second channel pattern in the second region, wherein the first channel pattern comprises a first plurality of semiconductor patterns vertically stacked on the substrate, a first inner region, and a first outer region, and wherein the second channel pattern comprises a second plurality of semiconductor patterns vertically stacked on the substrate, a second inner region, and a second outer region;
forming a high-k dielectric layer covering the first channel pattern and the second channel pattern;
forming a first protective mask on the high-k dielectric layer in the first region and the second region;
removing the first protective mask from the first outer region and the second outer region; and
forming an additional mask layer surrounding the first channel pattern and the second channel pattern, wherein the additional mask layer does not have etch selectivity with the first protective mask,
wherein the first inner region comprises spaces between adjacent semiconductor patterns of the first plurality of semiconductor patterns, and the first outer region comprises a space around the first plurality of semiconductor patterns excluding the first inner region, and
wherein the second inner region comprises spaces between adjacent semiconductor patterns of the second plurality of semiconductor patterns, and the second outer region comprises a space around the second plurality of semiconductor patterns excluding the second inner region.

2. The method of claim 1, further comprising, after the forming the additional mask layer:
forming a first photo mask layer in the first region; and
removing the additional mask layer and the first protective mask from the second region by using the first photo mask layer as an etch mask.

3. The method of claim 2, further comprising, after the removing the additional mask layer and the first protective mask from the second region, forming a conductive layer which fills the second inner region and which also fills at least part of the second outer region.

4. The method of claim 3, further comprising, after the forming the conductive layer: forming a second photo mask layer covering the conductive layer in the second region; and
removing the additional mask layer and the first protective mask from the first region.

5. The method of claim 3, wherein the conductive layer fills the first inner region and the second inner region.

6. The method of claim 1, wherein the removing of the first protective mask does not remove the first protective mask from the first inner region or the second inner region.

7. The method of claim 1, further comprising, after the forming the additional mask layer, forming a second protective mask on the additional mask layer, wherein the second protective mask has etch selectivity with the additional mask layer.

8. The method of claim 7, wherein the first protective mask and the additional mask layer each comprise at least one of: aluminum, a mixture of aluminum and another metal, an oxide of aluminum, an oxide of a mixture of aluminum and another metal, a carbide of aluminum, a carbide of a mixture of aluminum and another metal, a silicide of aluminum, a silicide of a mixture of aluminum and another metal, a silicon nitride of aluminum, a silicon nitride of a mixture of aluminum and another metal, a silicon carbide of aluminum, or a silicon carbide of a mixture of aluminum and another metal.

9. The method of claim 8, wherein the second protective mask comprises at least one of: titanium, tantalum, a combination of titanium and tantalum, an oxide of titanium, an oxide of tantalum, an oxide of a combination of titanium and tantalum, a nitride of titanium, a nitride of tantalum, a nitride of a combination of titanium and tantalum, a carbide of titanium, a carbide of tantalum, a carbide of a combination of titanium and tantalum, a silicide of titanium, a silicide of tantalum, a silicide of a combination of titanium and tantalum, a silicon nitride of titanium, a silicon nitride of tantalum, a silicon nitride of a combination of titanium and tantalum, or a silicon carbide of titanium, a silicon carbide of tantalum, or a silicon carbide of a combination of titanium and tantalum.

10. The method of claim 7, wherein the additional mask layer is disposed between the second protective mask and the high-k dielectric layer.

11. The method of claim 1, further comprising, after the forming the high-k dielectric layer and before the forming the first protective mask, forming a conductive layer covering the high-k dielectric layer, wherein the conductive layer fills only a part of the first inner region and the second inner region.

12. The method of claim 11, wherein the conductive layer comprises at least one of:
one of aluminum, magnesium, calcium, strontium, vanadium, niobium, scandium, yttrium, lanthanum;
a combination of one or more of aluminum, magnesium, calcium, strontium,
vanadium, niobium, scandium, yttrium and lanthanum;
a silicate of aluminum, magnesium, calcium, strontium, vanadium, niobium,
scandium, yttrium, lanthanum, or any combination thereof;
an oxynitride of aluminum, magnesium, calcium, strontium, vanadium, niobium, scandium, yttrium, lanthanum, or any combination thereof;
a silicon oxynitride of aluminum, magnesium, calcium, strontium, vanadium, niobium, scandium, yttrium, lanthanum, or any combination thereof;
a P-type work function metal; or
an N-type work function metal.

13. The method of claim 11, further comprising, after the forming the additional mask layer:
forming a photo mask layer in the first region;
removing the additional mask layer, the first protective mask, and the conductive layer from the second region by using the photo mask layer as an etch mask; and
removing the photo mask layer, the additional mask layer, and the first protective mask from the first region.

14. The method of claim 1, wherein a thickness of the additional mask layer on any one of the first channel pattern and the second channel pattern is less than a thickness of the first protective mask on any one of the first inner region and the second inner region.

15. A method of manufacturing a semiconductor device, the method comprising:
preparing a substrate comprising a first region and a second region next to the first region;
forming a first channel pattern in the first region and forming a second channel pattern in the second region, wherein the first channel pattern comprises a first plurality of semiconductor patterns vertically stacked on the substrate, a first inner region, and a first outer region, and wherein the second channel pattern comprises a second plurality of semiconductor patterns vertically stacked on the substrate, a second inner region, and a second outer region;
forming a first protective mask surrounding the first channel pattern and the second channel pattern;
removing the first protective mask from the first outer region and the second outer region;
forming an additional mask layer surrounding the first channel pattern and the second channel pattern, wherein the additional mask layer does not have etch selectivity with the first protective mask;
forming, on the additional mask layer, a second protective mask having etch selectivity with the first protective mask and the additional mask layer;
forming a first photo mask layer covering the second protective mask in the first region; and
exposing a sidewall of the second protective mask and a sidewall of the additional mask layer in a boundary between the first region and the second region by removing the second protective mask, the additional mask layer, and the first protective mask from the second region by using the first photo mask layer as an etch mask,
wherein the first inner region comprises spaces between adjacent semiconductor patterns of the first plurality of semiconductor patterns, and the first outer region comprises a space around the first plurality of semiconductor patterns excluding the first inner region, and
wherein the second inner region comprises spaces between adjacent semiconductor patterns of the second plurality of semiconductor patterns, and the second outer region comprises a space around the second plurality of semiconductor patterns excluding the second inner region.

16. The method of claim 15, further comprising, after the forming the first channel pattern and the second channel pattern and before the forming the first protective mask, forming a conductive layer surrounding the first channel pattern and the second channel pattern.

17. The method of claim 16, further comprising, after the exposing the sidewall of the second protective mask and the sidewall of the additional mask layer, removing the conductive layer from the second region.

18. The method of claim 15, further comprising, after the exposing the sidewall of the second protective mask and the sidewall of the additional mask layer, forming a conductive layer covering the first channel pattern and the second channel pattern.

19. The method of claim 18, further comprising, after the forming the conductive layer:
forming a second photo mask layer covering the conductive layer in the second region; and
removing the conductive layer from the first region by using the second photo mask layer as an etch mask.

20. A method of manufacturing a semiconductor device, the method comprising:
preparing a substrate comprising a first region and a second region next to the first region;
forming a first channel pattern in the first region and forming a second channel pattern in the second region, wherein the first channel pattern comprises a first plurality of semiconductor patterns vertically stacked on the substrate and a first inner region, and wherein the second channel pattern comprises a second plurality of semiconductor patterns vertically stacked on the substrate and a second inner region;
forming a high-k dielectric layer covering the first channel pattern and the second channel pattern;
forming a first protective mask filling the first inner region and the second inner region and surrounding the first channel pattern and the second channel pattern in an outer region, wherein the outer region comprises a remaining space on the first plurality of semiconductor patterns and the second plurality of semiconductor patterns excluding the first inner region and the second inner region;
exposing at least part of a surface of the high-k dielectric layer by removing the first protective mask from the outer region;
forming an additional mask layer covering the exposed surface of the high-k dielectric layer and sidewalls of the first protective mask, wherein the additional mask layer has no etch selectivity with the first protective mask;
forming the first protective mask and a second protective mask having etch selectivity with the additional mask layer on the additional mask layer;
forming a photo mask layer covering the second protective mask in the first region; and
removing the second protective mask, the additional mask layer, and the first protective mask from the second region by using the photo mask layer as an etch mask.
